(19) United States
(12) Patent Application Publication
(10) Pub. No.: US 2016/0270248 A1
(43) Pub. Date: Sep. 15, 2016

(54) MODULAR UPGRADEABLE VEHICLE INFOTAINMENT SYSTEM WITH CAPABILITY TO EXCHANGE HOST AND SLAVE RESPONSIBILITIES

(71) Applicant: Panasonic Automotive Systems Company of America, Division of Panasonic Corporation of North America, Peachtree City, GA (US)

(72) Inventors: HANS ALFRED TROEMEL, JR., SHARPSBURG, GA (US); THOMAS RAY BURNS, ATLANTA, GA (US)

(73) Assignee: Panasonic Automotive Systems Company of America, Division of Panasonic Corporation of North America

(21) Appl. No.: 15/060,280

(22) Filed: Mar. 3, 2016

Related U.S. Application Data
(60) Provisional application No. 62/132,441, filed on Mar. 12, 2015.

(51) Int. Cl. H05K 7/02; H05K 13/00; B60R 11/02

(52) U.S. Cl. CPC H05K 7/026; B60R 11/02; H05K 13/0023

(57) ABSTRACT

An infotainment arrangement for a motor vehicle includes an automotive-specific, factory-installed portion having a complete and functional infotainment system with a plurality of non-upgradeable electronic components. A non-factory-installed upgrade portion is in electronic communication with the automotive-specific, factory-installed portion. The non-factory-installed upgrade portion upgrades and/or adds to functionality of the automotive-specific, factory-installed portion without changing the automotive-specific, factory-installed portion.

### CROSS-REFERENCE TO RELATED APPLICATIONS

This application claims the benefit of U.S. Provisional Application No. 62/132,441 filed on Mar. 12, 2015, which the disclosure of which is hereby incorporated by reference in its entirety for all purposes.

### FIELD OF THE INVENTION

The disclosure relates to an infotainment system for a motor vehicle for any mode of transportation.

### BACKGROUND OF THE INVENTION

Infotainment systems on motor vehicles are generally not upgradeable. The consumer electronics market not only changes software but continuously upgrades the electronics as well. This constant rapid evolution of the consumer market quickly forces the electronics of the infotainment system to become obsolete within a few years, and yet the vehicle may be in service for over ten years. Thus, the majority of a vehicle's life may be spent with obsolete electronics.

### SUMMARY

Disclosed herein is a system partitioning and architecture wherein it is possible to upgrade, swap out, or exchange a module or modules which may include wired and/or wireless in-cabin interfaces. The module(s) may be upgraded, swapped out, or exchanged to communicate with consumer electronics, to upgrade the processing of vehicle/infotainment audio/video/data, and/or to increase internet/data bandwidth for vehicle/infotainment applications.

The system partitioning/architecture provides a physical division between the permanent automotive-specific original equipment manufacturer (OEM) vehicle-centric components and the modular upgradable components. The permanent components may include an external radio frequency (RF) interface (e.g., broadcast audio systems, broadcast television systems, cellular systems, global navigation satellite system (GNSS) receivers, wireless transceivers, etc.), audio power amplifiers, automotive displays/clusters/heads up displays (HUD), and/or vehicular communication buses. All of these elements may be tailored or tuned to the vehicle for best performance or styling. In contrast, the modular upgradeable components may include the main processor or system on chip (SoC) of the infotainment system along with the latest electronic, mechanical, or software interfaces to the consumer devices (e.g., phones, tablets, etc.). The permanent and modular systems may be connected via high bandwidth bi-directional audio/video/data communication buses and signaling.

The invention may provide the ability to upgrade the vehicle infotainment system with minimal impact to the factory-installed vehicle systems over the lifetime of the vehicle. This architecture provides the ability to keep better pace with the current state of consumer electronics, while possibly adding features to the vehicle system in the future as well. In essence, the inventive architecture “future-proofs” the vehicle infotainment system. The architecture enables quick and cost effective upgrading of the components of the system that are most likely to be in need of an upgrade in the future.

In one embodiment, the invention comprises deploying a basic but complete infotainment system on all vehicles, and then adding any additional desired components or features for certain models of vehicles without impacting the base system.

The architecture binds the system to the elements that are vehicle specific, leaving open many possible upgrade paths that are more specific to the human-machine interface (HMI), user experience, external connectivity, and other technologies that are not necessarily a part of the vehicle-specific components.

A core hardware system can be qualified for use and deployed across a broad range of vehicles. The features or capabilities are upgraded without having knowledge in advance of what those features or capabilities might be, because the core system can hand over control to one of the newly installed components. These upgrades can be installed without having to re-qualify the already installed components.

The system may be upgraded by replacement and/or exchanging of the modular units. This approach avoids system redundancy and maintains cost effectiveness. In one embodiment, a factory installed unit has a main system on chip (SoC) and connections with a blank or empty dock. This approach saves the cost of the modular unit housing and power supplies. This method is valid, but provides redundancy to the overall system cost once the first modular unit is applied.

In another embodiment, the invention comprises an automotive-specific, factory-installed portion having a complete and functional infotainment system with a plurality of non-upgradeable electronic components. A non-factory-installed upgrade portion is in electronic communication with the automotive-specific, factory-installed portion. The non-factory-installed upgrade portion improves and/or adds to functionality of the automotive-specific, factory-installed portion without changing the automotive-specific, factory-installed portion.

In yet another embodiment, the invention comprises a method of maintaining an infotainment arrangement in a motor vehicle, including installing at a factory an automotive-specific portion of the infotainment arrangement in the vehicle. The automotive-specific, factory-installed portion includes a complete and functional infotainment system having a plurality of non-upgradeable electronic components. Outside of the factory, an upgrade portion of the infotainment arrangement is installed in the vehicle. Electronic communication is performed between the automotive-specific, factory-installed portion and the upgrade portion.

In still another embodiment, the invention comprises a motor vehicle, including an infotainment arrangement having an automotive-specific portion installed in the vehicle at an automobile assembly plant. The automotive-specific portion includes a complete and functional infotainment system having a plurality of non-upgradeable electronic components. An upgrade portion is electronically connected to the automotive-specific portion. The upgrade portion is installed in the vehicle at an automobile dealership and improves performance and/or functionality of the infotainment arrangement.

### BRIEF DESCRIPTION OF THE DRAWINGS

A better understanding of the present invention will be had upon reference to the following description in conjunction with the accompanying drawings.

FIG. 1 is a block diagram of one example embodiment of a vehicle infotainment system of the present invention.

### DETAILED DESCRIPTION OF THE PREFERRED EMBODIMENTS

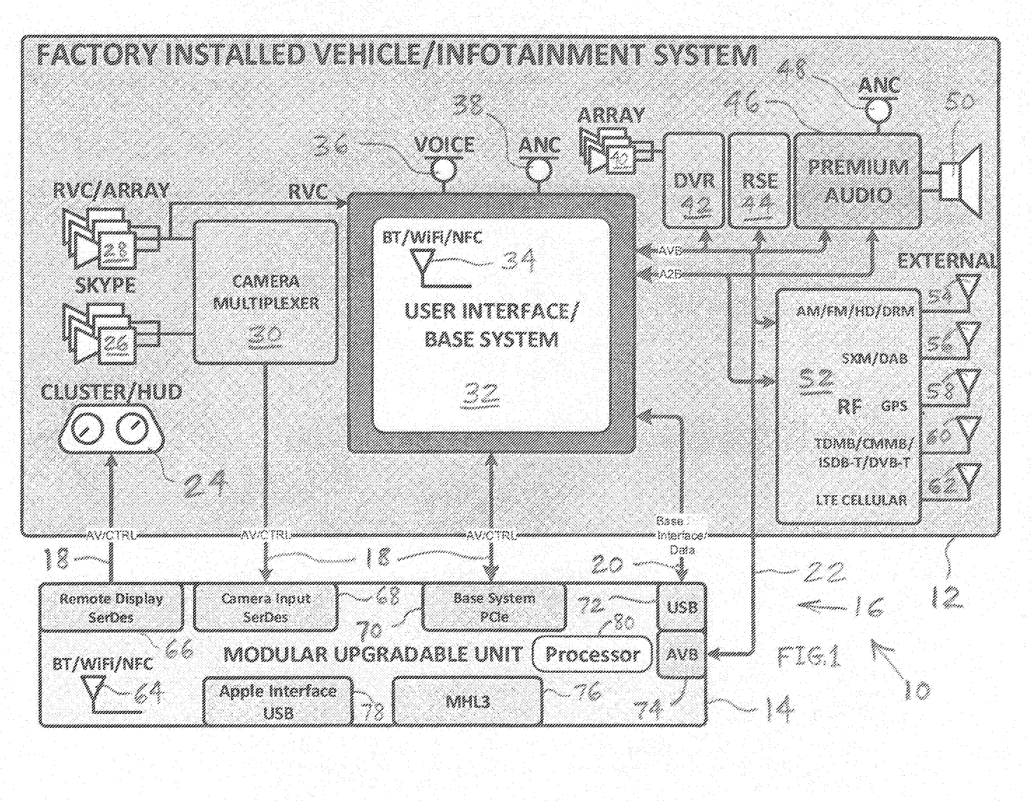

FIG. 1 illustrates one embodiment of a vehicle infotainment system 10 of the present invention including a permanent factory installed portion 12 and an upgradeable modular unit 14. Each of permanent portion 12 and modular unit 14 may be contained in a separate, respective housing. Permanent portion 12 and modular unit 14 may be interconnected by a connector arrangement 16 including one or more cables and connectors. The conductive lines within the connector arrangement 16 include audio/video data bus with control signaling 18, a base interface/data signaling 20, and an audio/video bridge (AVB) signaling 22 which may carry time-stamped Ethernet data. It is also possible within the scope of the invention for connector arrangement 16 to be replaced with a wireless interface, or for any of the individual conductors within connector arrangement 16 to be replaced by a wireless link.

Audio/video data bus with control signaling 18 may carry uncompressed data without any latency. Alternatively, audio/video data bus with control signaling 18 may carry compressed data with latency in the range of milliseconds. In one embodiment, audio/video data bus with control signaling 18 may carry about three gigabits of data in each direction.

In the embodiment shown, permanently factory installed portion 12 includes an instrument cluster/heads up display (HUD) 24, Skype cameras 26, Rear View Camera (RVC)/array cameras 28, a camera multiplexer 30, a user interface/base system 32 having a BT (Bluetooth)/WIFI/NFC (near field communication) antenna 34, a voice microphone 36, an ancillary microphone 38, a camera array 40, a digital video recorder (DVR) 42, rear seat entertainment (RSE) subsystem 44, a premium audio subsystem 46, an ancillary microphone 48, a loudspeaker 50, and a radio frequency (RF) antenna array 52 including an AM/FM/high definition (HD)/digital radio mondiale (DRM) antenna 54, a SiriusXM (SXM)/digital audio broadcasting (DAB) antenna 56, a global positioning system (GPS)/GNSS antenna 58, a Terrestrial—Digital Multimedia Broadcasting (T-DMB)/China Mobile Multimedia Broadcasting (CMMB)/Integrated Services Digital Broadcasting-Terrestrial (ISDB-T)/Digital Video Broadcasting-Terrestrial (DVB-T) antenna 60, and a long-term evolution (LTE) cellular antenna 62.

In the embodiment shown, upgradeable modular unit 14 includes, but is not limited to, a BT/WiFi/NFC antenna 64, a remote display serializer/deserializer 66, a camera input serializer/deserializer 68, a base system PCle 70, a USB port 72, an audio/video bridge 74, mobile high-definition link (MHL3) 76, an Apple Interface USB port 78, and a microprocessor 80 in communication with each of the other above-identified components of upgradeable modular unit 14. Apple Interface USB port 78 may be connectable to a personal electronic device, such as a mobile phone. A processor in the personal electronic device may be used as the primary processor of, and may perform most of the processing for, vehicle infotainment system 10.

During use, the components of upgradeable modular unit 14 may become obsolete due to age and/or better or more widely accepted technology coming to the consumer electronics market. When such obsolescence of one or more of the components of upgradeable modular unit 14 occurs, the owner of the vehicle may swap out the obsolete modular unit 14 with an upgraded modular unit 14. The owner of the vehicle may swap out modular unit 14 himself by disconnecting the obsolete modular unit 14 from the vehicle dashboard. In one embodiment, modular unit 14 may be disconnected from the vehicle dashboard simply by pulling modular unit 14 out of a recess in the dashboard in a single linear motion. Similarly, the new, upgraded modular unit 14 may be inserted into the dashboard by simply pushing modular unit 14 into the recess in the dashboard in a single linear motion until it snaps into place. The new, upgraded modular unit 14 may be fully mechanically and electrically connected to the dashboard as soon as the upgraded modular unit 14 snaps into place. The direction of pushing may be in a direction opposite to the direction in which unit 14 was pulled out during removal. Modular unit 14 may be hot swappable such that the new modular unit 14 is operable as soon as it is snapped into place.

In another embodiment, specialized or customized tools are required to remove the obsolete modular unit 14 from the dashboard such that replacing modular unit 14 with another one must be performed by personnel at the dealership who have the required tools.

In another embodiment, automotive-specific features of the infotainment system are included in an extensible, permanently factory installed portion, and user/HMI/outside connectivity portions of the infotainment system are included in the upgradeable modular unit. The automotive-specific side of the system may include built-in electrical hardware and software that connects to, or is part of, the automobile. The user/HMI/outside connectivity portion of the infotainment system is that part that is changeable, upgradeable, and extensible without having to alter the built-in automotive-specific components.

The automotive-specific portion of the infotainment system may exist within the vehicle and control the entire infotainment system, including the user/HMI/outside connectivity portion of the infotainment system. However, if there is no user/HMI/outside connectivity portion installed in the infotainment system, then the automotive-specific portion of the extensible infotainment system can function independently as a complete infotainment system. Yet, it may still be possible to add-on additional module(s) (e.g., in the form of a user/HMI/outside connectivity portion) that may be capable of taking over command and control of the automotive-specific portion of the extensible infotainment system.

As described above, the factory-installed stand-alone system can partially or fully swap roles with the add-on modular replaceable unit to become a slave device or peripheral to the add-on modular replaceable unit. This role exchange enables the new add-on module to assume partial or complete control of the infotainment system, and the factory install peripherals may be treated as new peripheral assets to leverage.

The extensibility feature of the inventive infotainment system may enable vehicles to be equipped with a stand-alone infotainment system that has very basic or mid-range capabilities, but be upgradeable with external module(s) to thereby be transformed to a mere portion or component of a more capable, full-featured system that is controlled by the added external module(s). This may be accomplished without replacing or changing any component of the original automotive-specific hardware and software.

The extensible infotainment system may enable vehicles to be equipped with infotainment capabilities, and later on be upgraded to newer or more capable technologies without removing or replacing the original controlling system. Rather, the original controlling system may be made use of as a non-controlling slave. This provides simpler deployment of basic-level infotainment hardware on low-end vehicles, and extends capabilities for higher-end vehicles at the time of production or manufacture. The inventive extensible infotainment system may enable extension of the base system to accommodate new technical standards and incorporate new technologies without having to know in advance what those new standards and technologies may be, or what the requirements will be for controlling the new technologies. With the inventive extensible infotainment system, only the automotive-specific portion of the system may remain unchanged over the life of the vehicle.

A core hardware subsystem can be qualified for use as the automotive-specific portion of the system and may be deployed across a broad range of vehicles. This core hardware subsystem can then be upgraded in terms of features or capabilities without having to know in advance what those features or capabilities might be, because the core hardware subsystem can hand over control to one of the newly installed components. Such upgrades can be installed in the vehicle without having to re-qualify the already installed components of the core hardware subsystem.

The foregoing description may refer to “motor vehicle”, “automobile”, “automotive”, or similar expressions. It is to be understood that these terms are not intended to limit the invention to any particular type of transportation vehicle. Rather, the invention may be applied to any type of transportation vehicle whether traveling by air, water, or ground, such as airplanes, boats, etc.

The foregoing detailed description is given primarily for clearness of understanding and no unnecessary limitations are to be understood therefrom for modifications can be made by those skilled in the art upon reading this disclosure and may be made without departing from the spirit of the invention.

What is claimed is:

1. An infotainment arrangement for a motor vehicle, comprising:
an automotive-specific, factory-installed portion, the automotive-specific, factory-installed portion including a complete and functional infotainment system having a plurality of non-upgradeable electronic components; and
a non-factory-installed upgrade portion in electronic communication with the automotive-specific, factory-installed portion, the non-factory-installed upgrade portion being configured to improve and/or add to functionality of the automotive-specific, factory-installed portion without changing the automotive-specific, factory-installed portion.

2. The arrangement of claim 1 wherein the non-factory-installed upgrade portion is connected to the automotive-specific, factory-installed portion by at least one cable or connector.

3. The arrangement of claim 1 wherein the non-factory-installed upgrade portion is configured to be communicatively coupled to a personal electronic device.

4. The arrangement of claim 3 wherein the non-factory-installed upgrade portion is configured to use a processor in the personal electronic device to perform a majority of processing required by the arrangement.

5. The arrangement of claim 1 wherein the non-factory-installed upgrade portion is configured to be removed from the vehicle by pulling the non-factory-installed upgrade portion out of the vehicle in a first single, linear motion in a first direction, and the non-factory-installed upgrade portion is configured to be installed in the vehicle by pushing the non-permanent upgradeable portion into a recess of the vehicle in a second single, linear motion in a second direction opposite to the first direction until the non-factory-installed upgrade portion snaps into place.

6. The arrangement of claim 1 wherein the automotive-specific, factory-installed portion includes at least one a user interface, at least one antenna, at least one loudspeaker, and at least one radio receiver.

7. The arrangement of claim 1 wherein the non-factory-installed upgrade portion includes a microprocessor and at least one communication port, and is configured to take over control of the automotive-specific, factory-installed portion.

8. The arrangement of claim 1 wherein the non-factory-installed upgrade portion is configured to take over control of an infotainment system including both the automotive-specific, factory-installed portion and the non-factory-installed upgrade portion.

9. A method of maintaining an infotainment arrangement in a motor vehicle, comprising:
installing at a factory an automotive-specific portion of the infotainment arrangement in the vehicle, the automotive-specific, factory-installed portion including a complete and functional infotainment system having a plurality of non-upgradeable electronic components;
installing outside of the factory an upgrade portion of the infotainment arrangement in the vehicle; and
performing electronic communication between the automotive-specific, factory-installed portion and the upgrade portion.

10. The method of claim 9 further comprising connecting the upgrade portion to the automotive-specific portion by at least one cable or connector.

11. The method of claim 9 further comprising communicatively coupling the upgrade portion to a personal electronic device.

12. The method of claim 11 further comprising using a processor in the personal electronic device to perform a majority of processing required by the system.

13. The method of claim 9 wherein the upgrade portion is installed in the vehicle by pushing the upgrade portion into a recess of the vehicle in a single, linear motion until the upgrade portion snaps into place within the recess.

14. The method of claim 9 further comprising using the upgrade portion to control the automotive-specific portion.

15. The method of claim 9 wherein the upgrade portion is installed in the vehicle at an automobile dealership by use of specialized tools.

16. A motor vehicle, comprising an infotainment arrangement including:
an automotive-specific portion configured to be installed in the vehicle at an automobile assembly plant, the automotive-specific portion including a complete and functional infotainment system having a plurality of non-upgradeable electronic components; and
an upgrade portion electronically connected to the automotive-specific portion, the upgrade portion being configured to be installed in the vehicle at an automobile dealership and to improve performance and/or functionality of the infotainment arrangement.

17. The vehicle of claim 16 wherein the upgrade portion is configured to be:
removed from the vehicle by pulling the upgrade portion out of the vehicle in a first single, linear motion in a first direction; and
installed in the vehicle by pushing the upgrade portion into a recess of the vehicle in a second single, linear motion in a second direction opposite to the first direction.

18. The vehicle of claim 16 wherein the upgrade portion is connected to the automotive-specific portion by at least one cable or connector.

19. The vehicle of claim 16 wherein the upgrade portion is configured to be communicatively coupled to a personal electronic device.

20. The vehicle of claim 19 wherein the upgrade portion is configured to use a processor in the personal electronic device to perform a majority of processing required by the arrangement.

21. The vehicle of claim 16 wherein the automotive-specific portion is contained within a first housing, and the upgrade portion is contained within a second housing.

22. The vehicle of claim 16 wherein the automotive-specific portion includes at least one camera, at least one microphone, an instrument cluster, a user interface, at least one antenna, and at least one loudspeaker.

23. The vehicle of claim 16 wherein the upgrade portion includes a microprocessor and at least one communication port.
